(19) United States
(12) Patent Application Publication
(10) Pub. No.: US 2012/0217512 A1
(43) Pub. Date: Aug. 30, 2012

(54) LATERAL POWER TRANSISTOR DEVICE AND METHOD OF MANUFACTURING THE SAME

(76) Inventor: Philippe Renaud, Cugnaux (FR)

(21) Appl. No.: 13/504,744

(22) PCT Filed: Nov. 19, 2009
(86) PCT No.: PCT/IB2009/056012

§ 371 Date: Apr. 27, 2012

(51) Int. Cl. H01L 29/20; H01L 29/205; H01L 21/768; H01L 29/78

(52) U.S. Cl. 257/76; 257/192; 257/190; 438/675; 257/E29.255; 257/E29.089; 257/E29.091; 257/E21.586

(57) ABSTRACT

A lateral power transistor device comprises a substrate and a multi-layer mesa structure comprising a heterojunction. A filled trench region is located adjacent the multi-layer mesa structure, the filled trench region being occupied by a metal.

### FIELD OF THE INVENTION

This invention relates to a lateral power transistor device , a semiconductor die o and a method of manufacturing a lateral power transistor device.

### BACKGROUND OF THE INVENTION

As a result of the increasingly important environmental disadvantages of the internal combustion engine, pressure continues to mount on automotive manufacturers to reduce carbon dioxide (CO₂) emissions of engines of vehicles they make. To this end, vehicle manufacturers and others are developing Hybrid Vehicle (HV) technology, Electric Vehicle (EV) technology, Fuel Cell (FC) technology and Advanced Biofuel technology, amongst other technologies as a way of reducing the carbon footprint of vehicles manufactured.

In relation to HV technology, it is known for a so-called hybrid vehicle to comprise a powertrain that is controlled by a hybrid vehicle control system. The powertrain comprises an internal combustion engine and an electric motor coupled to drive wheels via a power-split device that enables the drive wheels to be powered by the combustion engine alone, the electric motor alone or both the combustion engine and the electric motor together, allowing the combustion engine to maintain a most efficient load and speed range at a given time. The electric motor is powered by a high voltage battery. A so-called “inverter assembly” is provided that comprises an inverter and a so-called “boost converter”. The inverter converts high voltage direct current from the high voltage battery of the vehicle into a three-phase alternating current for powering the electric motor. Sometimes the powertrain of the vehicle comprises more than one electric motor.

In order to provide the three-phase alternating current, the output voltage of the high voltage battery is stepped up by the boost converter from, for example, 200V to 600V. The inverter is then responsible for providing the three-phase alternating current, derived from the stepped-up voltage provided by the boost converter. In order to generate the three-phase alternative current, it is known for the inverter to comprise a bank of Insulated-Gate Bipolar Transistors (IGBTs) and parallel diodes for power modulation, the IGBTs constituting power switches.

However, for future hybrid and other electrically powered vehicles, greater demands will be made on the inverter, including low energy loss, reduced size and cost effectiveness. Furthermore, the semiconductor devices of the inverter will need to be formed from wideband gap semiconductor materials and exhibit high breakdown voltage and be able to withstand high operating temperatures.

While performance of silicon-based IGBTs is currently acceptable, these devices are less likely to perform well in respect of high current density demands, high power source voltages and high temperature operation demands that will be placed on the silicon IGBTs by future vehicle designs.

Promising candidate semiconductor materials from which to fabricate power transistors is gallium nitride and other III-V nitrides. However, these devices typically require a gallium nitride (GaN) substrate. Growth of gallium nitride substrates on a silicon substrate for subsequent separation therefrom is difficult due to stresses caused by lattice mismatches. In this respect, difficulties have been encountered growing the gallium nitride layer sufficiently thick without the gallium nitride layer cracking when attempts are made to separate the gallium nitride layer from the silicon substrate.

To mitigate this problem, it is also known to grow the gallium nitride substrate on a Silicon Carbide substrate that has a closer lattice match with the crystalline structure of the gallium nitride grown thereon. However, the production of gallium nitride substrates of a desired thickness on Silicon Carbide substrates is costly and so a less desired manufacturing option.

Marianne Germain, “IMEC enlarges nitride epiwafers”, Compound Semiconductor, Angel Business Communications, Volume 14, number 11, Dec. 2008, pages 23 to 25 describes a lateral Field Effect Transistor (FET) structure comprising a silicon substrate upon which an aluminium gallium nitride “interlayer” is disposed, an aluminium gallium nitride buffer layer being disposed on the aluminium gallium nitride interlayer. A mesa structure comprising, in part, the aluminium gallium nitride buffer layer is also provided and further comprises a gallium nitride channel layer disposed upon the aluminium gallium nitride buffer layer and an aluminium gallium nitride barrier layer disposed on the gallium nitride channel layer. A capping layer is also disposed upon the aluminium gallium nitride barrier layer. A gate contact is disposed upon the capping layer and source and drain contacts are also disposed on the capping layer, but extend down side surfaces of the mesa structure. The authors claim that a more than 50% improvement in breakdown voltage can be achieved by the provision of the double heterostructure.

However, in order to meet future demands of such lateral-type power transistor devices, it is desirable to improve the breakdown voltage achievable further, as well as reliability, current capability, heat dissipation, Rₒₙ and die space occupied by the power transistor device.

### SUMMARY OF THE INVENTION

The present invention provides a lateral power transistor device, a semiconductor die and a method of manufacturing a lateral power transistor device as described in the accompanying claims.

Specific embodiments of the invention are set forth in the dependent claims.

These and other aspects of the invention will be apparent from and elucidated with reference to the embodiments described hereinafter.

### BRIEF DESCRIPTION OF THE DRAWINGS

Further details, aspects and embodiments of the invention will be described, by way of example only, with reference to the drawings. In the drawings, like reference numbers are used to identify like or functionally similar elements. Elements in the figures are illustrated for simplicity and clarity and have not necessarily been drawn to scale.

FIGS. 1 to 8 are schematic diagrams of exemplary stages of manufacture by following steps of a method of manufacture of a lateral power transistor device constituting an embodiment of the invention; and

FIG. 9 is a flow diagram of exemplary steps of the method associated with FIGS. 1 to 8.

### DETAILED DESCRIPTION OF THE PREFERRED EMBODIMENTS

Since the illustrated embodiments of the present invention may, for the most part, be implemented using electronic components and circuits known to those skilled in the art, details will not be explained in any greater extent than that considered necessary for the understanding and appreciation of the underlying concepts of the present invention and in order not to obfuscate or distract from the teachings of the present invention.

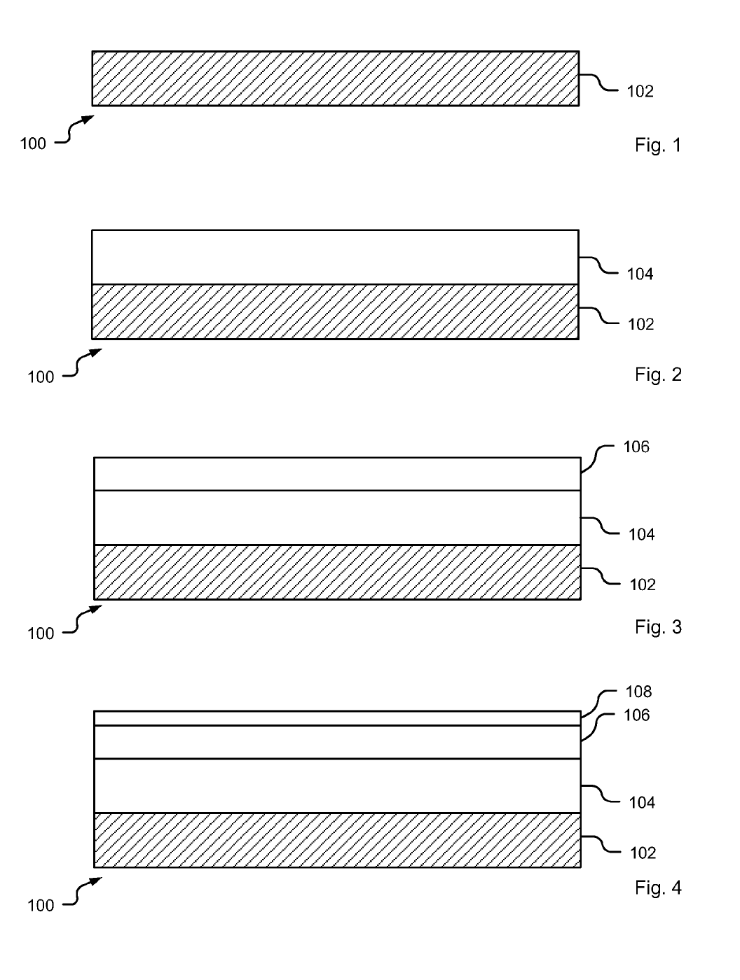

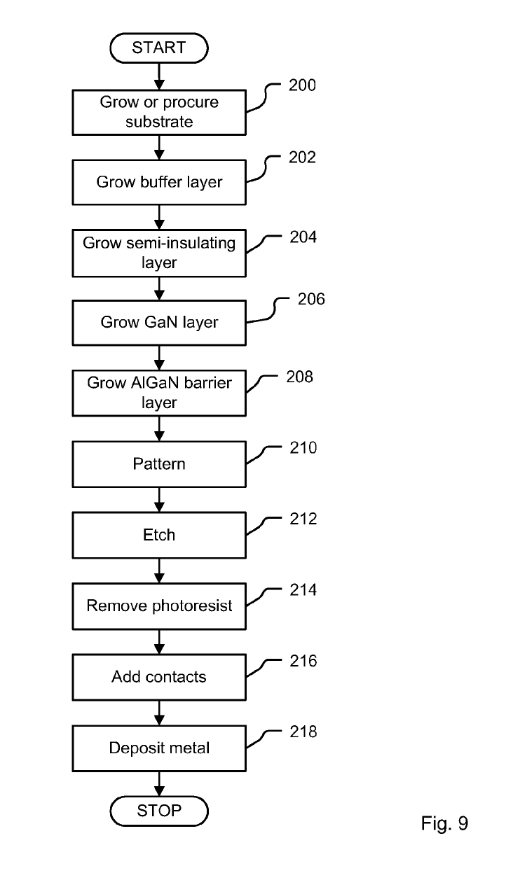

Referring to FIGS. 1 and 9, a wafer 100, initially comprising a substrate 102, may be provided (Step 200). In this example, the substrate 102 is a silicon substrate, but the substrate 102 can be formed from other materials, for example silicon carbide or a suitable nitride of a III-V semiconductor material such as one or more materials in the group consisting of: binary III-nitride material, ternary III-nitride material, quaternary III-nitride material or alloys or compounds thereof (such as AlN, InN, GaN, or the like). The substrate 102 may be formed by growing the substrate 102 on another, e.g. sapphire, substrate, for example using by a High Vapour Process Epitaxy (HVPE) process, and thereafter separating the substrate 102 from the other substrate according to any suitable separation or cleavage technique known in the art. The substrate 102 may have been separated from the other substrate before further manufacturing of the lateral power transistor device or, in particular in relation to a substrate formed from a suitable nitride of a III-V semiconductor material, the skilled person should also appreciate that the substrate 102 may remain disposed on the sapphire substrate and be processed using the processing steps described hereinbelow, after which the gallium nitride substrate can be separated from the sapphire substrate.

After provision of the silicon substrate 102, a buffer layer 104 (FIG. 2), may be disposed (Step 202) on the silicon substrate 102. The buffer layer 104 may match the lattice of the substrate to the lattice of the layers of the mesa-structure and/or electrically isolate the mesa-structure from the substrate. The buffer layer 104 may be formed to have a thickness of for example between about 0.5 μm and about 5 μm (although other depths may be used as well). The buffer layer 104 may be an epitaxial layer, for example grown using Molecular Beam Epitaxy (MBE) or Metal Organic Chemical Vapour Deposition (MOCVD). The buffer layer may for example be highly resistive or isolating and for instance be formed from a suitable nitride of a III-V semiconductor material, such as a not-intentionally doped aluminium gallium nitride layer

The formation of the buffer layer 104 may be followed by disposal (Step 204) of a semi-insulating layer 106 (FIG. 3) on the buffer layer 104. As shown in e.g. FIG. 7, after formation of the mesa-structure, the semi-insulating layer 106 is part of the mesa-structure and electrically isolates the other layers 108,110 of the mesa-structure from the substrate 102 and the buffer layer 104. The semi-insulating layer 106 may for example have a thickness of between about 0.05 μm and about 2 μm using MBE or MOCVD, although other thicknesses may be used as well. In this example, the semi-insulating layer 106 is p-type doped gallium nitride, where the dopant is magnesium (Mg). However, other dopants can be employed, for example, carbon (C) or iron (Fe) to increase the electrical resistance of the semi-insulating layer 108 or to develop a p-type behaviour by the layer. Alternatively, the semi-insulating layer 106 can be a layer of a suitable nitride of a III-V semiconductor material, for example: not-intentionally doped aluminium gallium nitride (AlGaN), not-intentionally doped indium gallium nitride (InGaN) or not-intentionally doped aluminium indium nitride (AlInN). If desired, other layers such as an aluminium gallium nitride or gallium nitride inter-layer (not shown) can be disposed on the substrate 102 using any suitable known technique prior to formation of the buffer layer 104 and the semi-insulating layer 106.

After formation of the semi-insulating layer 106, a heterojunction structure or other active device structure may be formed above the semi-insulating layer 106. In the shown example, the active device structure is a hetero junction which comprises a channel layer 108 and a barrier layer 110 (FIG. 4). The channel layer 108 may be a gallium nitride layer grown to a suitable thickness, for example of about 0.02 μm or more and/or about 0.5 μm or less (although other thicknesses may be used as well). The gallium nitride channel layer 108 may be grown (Step 206), on top of the semi-insulating layer 106 so that the gallium nitride layer 108 may be adjacent to, i.e. in direct contact with a surface of, the semi-insulating layer 106. To form the gallium nitride layer 108, any suitable growth technique can be employed, for example Molecular Beam Epitaxy (MBE) or Metal Organic Chemical Vapour Deposition (MOCVD). Although in this example the layer 108 is formed from gallium nitride, the skilled person should appreciate that other suitable materials, such as nitrides of a III-V semiconductor material may be used.

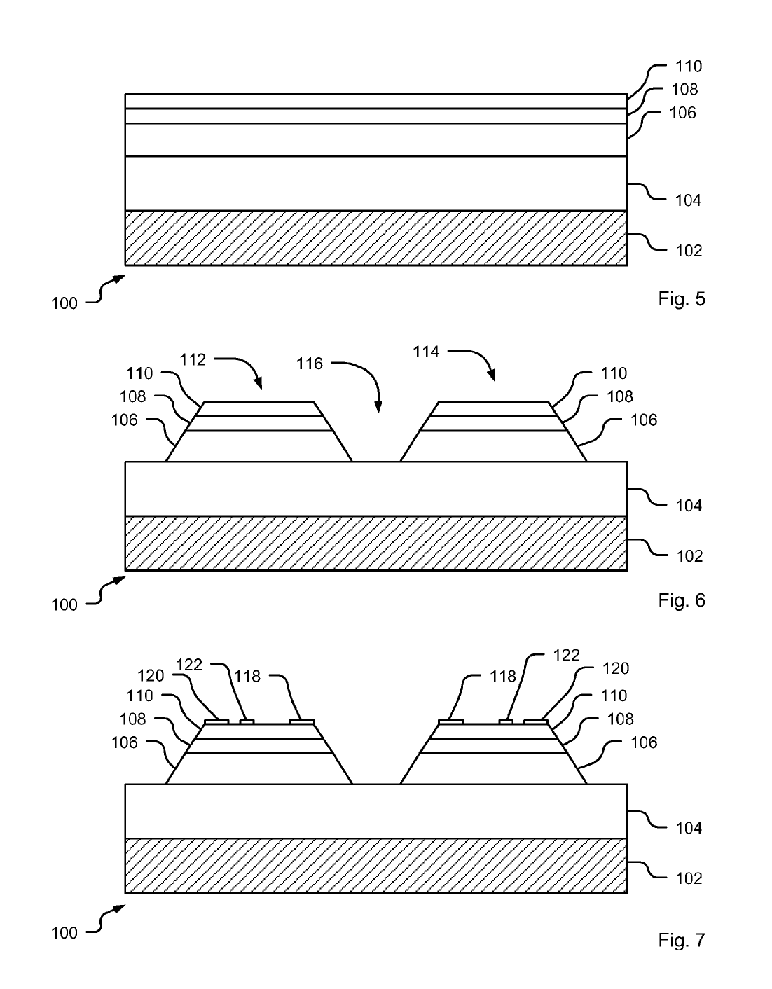

On the channel layer 108, a barrier layer 110 may be formed. For instance, an aluminium gallium nitride barrier layer 110 (FIG. 5) may be grown (Step 208) on the gallium nitride channel layer 108. A suitable thickness is found to be about or more 15 nm and /pr about 30 nm or less, although other thicknesses may be used as well. To form the aluminium gallium nitride layer 110 any suitable growth technique can be employed, for example Molecular Beam Epitaxy (MBE) or Metal Organic Chemical Vapour Deposition (MOCVD). The aluminium gallium nitride channel layer 110 may be grown (Step 208) on top of the gallium nitride layer 108. The aluminium gallium nitride barrier layer 110 is therefore disposed adjacent the gallium nitride layer 108.

The atomic percentage of aluminium in the aluminium gallium nitride can be of the order of about 20% to 30%, which can be expressed by the equation: AlₓGa₁₋ₓN, where x is between about 0.20 and about 0.30. Alternatively, the barrier layer 110 can be formed from indium gallium nitride (InGaN); the atomic percentage of the indium may be between about 10% and about 20%, which can be expressed by the equation: InₓGa₁₋ₓN, where x is between about 0.1 and about 0.2. As a further alternative, the barrier layer 110 can be formed from aluminium indium nitride (AlInN); the atomic percentage of the indium may be between about 10% and about 20%, which can be expressed by the equation: Al₁₋ₓInₓN, where x is between about 0.1 and about 0.2. The above materials used to form the barrier layer may be not intentionally doped and are examples of suitable nitrides of a III-V semiconductor material and any other suitable nitrides of a III-V semiconductor material may be used.

The layers 108,110 may be implemented in a manner suitable to form a hetero-junction. The layers 108,110 may be provided such that an interface is obtained at which the layers 108,110 are in contact with each other. The interface between the gallium nitride channel layer 108 and the barrier layer 110 serves as a heterojunction and so the power transistor device being formed is a High Electron Mobility Transistor (HEMT) or a Heterostructure Field Effect Transistor (HFET).

Along the interface, when the power transistor is in operation, a two dimensional electron gas (2DEG) may be formed in a part of the gallium nitride channel layer 108 directly adjacent to the interface. It will be understood that the term ‘two dimensional electron gas’ as used in this application, this includes a gas of electrons able to move in two dimensions, but tightly confined in the third dimension, as well a similar gas of holes. As shown in the FIGS, the layers 108,110 and the interface may be substantially planar and be oriented parallel to a top surface.e of the substrate 102

The layers 108,110 may be made from materials suitable for a hetero-junction., for example having different band-gaps. Thereby, the bandgaps will bend at the interface, as is generally known in the art, and a potential well may be obtained in which the 2DEG can be formed. The gallium nitride channel layer 108 may for example be not intentionally doped. Thereby, the gallium nitride channel layer 108 can be provided with a high resistivity and the leakage current of the HFET in the off-state may be reduced. Without wishing to be bound to any theory, it is believed that the high resistivity confines the electrons of the 2DEG within a sheet shaped region of the gallium nitride channel layer 108 at the interface thus inhibiting a leakage through parts of the gallium nitride channel layer 108 which are remote from the interface.

It should be apparent that other layers may be present and that the 2DEG may also be formed using other mechanisms and that other (combinations of) materials may be used to form the heterojunction. The layer 108,110 may for example have different lattice constants, and the layer 108 may exhibit a piezoelectric polarization in a transversal direction from the interface towards the substrate. Thereby, due to the different lattice constant, the layer 108 will be stressed or strained and will be charged at the interface. Thereby, the density of electrons at the interface may be increased.

A gallium nitride cap layer 111 may be provided (Step 209) in order to prevent oxidation of the aluminium gallium nitride barrier layer 110. As shown, the gallium nitride cap layer 111 may be grown on the aluminium gallium nitride barrier layer 110 so that the gallium nitride cap layer 114 is adjacent the aluminium gallium nitride barrier layer 110 and extends over the barrier layer 110 to shield the barrier layer from ambient influences, such as oxidizing fluids or other reactive fluids present.

After provision of the barrier layer 110, a multi-layer mesa structure 112 (FIG. 6) and another multi-layer mesa structure 114 may be formed, for example by locally removing the multi-layer stack comprising the semi-insulating layer 106, the gallium nitride layer 108 and the aluminium gallium nitride barrier layer 110.

For instance, a photoresist (not shown) may be disposed on the aluminium gallium nitride barrier layer 110, for example by spin coating, and the photoresist may be patterned (Step 210) using a suitable mask, thus locally exposing the multi-layer structure. For instance, the unhardened photoresist may be removed and the wafer may be exposed to an etchant (Step 212), resulting in the removal of the multilayer stack, down to the buffer layer 104 in the areas where the photoresist does not protect the multilayer stack. For example a plasma etching using chlorine gas as an etchant may be performed, so as to form a multi-layer mesa structure 112 (FIG. 6) and another multi-layer mesa structure 114. The multi-layer mesa structure 112 may therefore comprise the semi-insulating layer 106, the gallium nitride layer 108 and the aluminium gallium nitride barrier layer 110. Similarly, the another multi-layer mesa structure 114 may also comprise the semi-insulating layer 106, the gallium nitride layer 108 and the aluminium gallium nitride barrier layer 110. In this example, a suitable thickness of the multi-layer mesa structure 112 and the another multi-layer mesa structure 114 has been found to be between about 2 μm and about 3 μm, although other thicknesses may be used as well. If required, prior to etching the multi-layer mesa structure 114, a passivation layer (not shown), for example a silicon nitride (SiN) layer or a silicon dioxide (SiO₂), can be deposited, for example using Low Pressure Chemical Vapour Deposition (LPCVD) or sputtering. In such circumstances, as will be appreciated by the skilled person, photo-patterning and plasma etching may be required in order to create openings for the formation of the mesa structure and contacts.

A side surface of the multi-layer mesa structure 112 defines one side of a trench region 116 between the multi-layer mesa structure 112 and the another multi-layer mesa structure 114. A side surface of the another multi-layer mesa structure 114 defines an opposite side of the trench region 116 with respect to the side of the trench 116 defined by the multi-layer mesa structure 112. The so-called aspect ratio of the trench region 116 is shallow. In this respect, the trench region 116 may be wider than it is deep. The aspect ratio of the trench region 116 may therefore be, for example, more than 5:1, although other similarly shaped aspect ratios may be employed.

Once the trench region 116 has been formed, the photoresist may be removed (Step 214) and a drain contact 118 (FIG. 7), a source contact 120 and a gate contact 122 may then be formed (Step 216) on the barrier layer 110 of each of the multi-layer mesa structure 112 and the another multi-layer mesa structure 114. The aluminium gallium nitride barrier layer 110 may for example be implemented as a tunnelling layer which, after manufacturing of the structure, separates the terminals 118,120,122 from the gallium nitride layer 108 and which, when the transistor is operated after manufacturing of the semiconductor structure, allows a conduction between the drains and source 118,122 and the 2DEG via tunnelling of charge carriers through the aluminium gallium nitride barrier layer 110.

The drain, source and gate contacts 118, 120, 122 may be formed on the gallium nitride cap layer using any suitable metallisation technique. The drain and source contacts 118, 122, may be ohmic contacts and the gate contact 124 can be a Schottky contact, for example formed from nickel, platinum, molybdenum or iridium. Alternatively, the gate contact 122 can be Metal-Insulator-Semiconductor (MIS) contacts, for example silicon dioxide, silicon nitride, or hafnium oxide. The ohmic contacts may be formed from a combination of tantalum, titanium and aluminium according to any suitable technique known in the art and can be subject to rapid thermal anneal to diffuse metallic elements within the GaN cap layer 114 to form the so-called ohmic contacts.

Alternatively, the source and drain may also be in direct contact with the 2DEG and for example be provided in the aluminium gallium nitride barrier layer 110, to extend to at least the top surface or into of the gallium nitride layer 108 (for example by locally etching a recess in the barrier layer 110 to a desired depth and thereafter depositing the terminal layer(s) or/and by thermal diffusion of a suitable material, e.g. dopant, in the barrier layer 110). Alternatively, the source and/or drain may also be in contact with the 2DEG through a conductive path made by local thermal diffusion of metal and/or residual doping in the barrier layer 110 in order to make the barrier layer 110 electrically conducting in the area of the conductive path. The conductive path may also be provided in another way, such as by dopant implant followed by thermal diffusion in the area of the conductive path, for example by an implantation and subsequent activation.

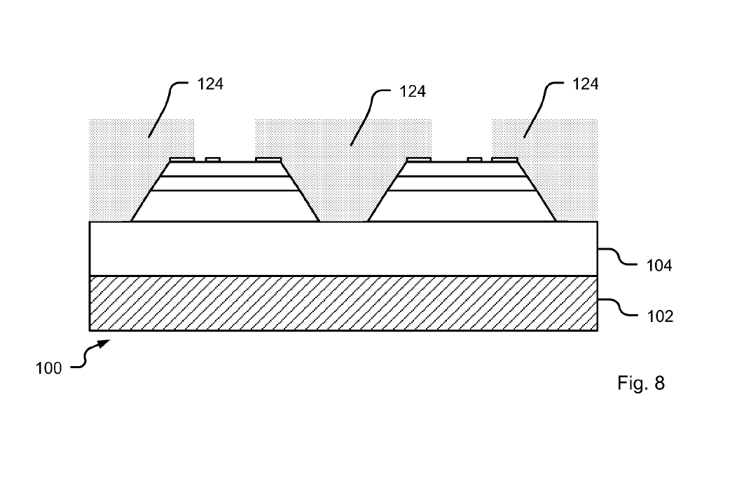

Referring to FIG. 8, after formation of the drain, source and gate contacts 118, 120, 122, the trench region 116 may be filled (Step 218) with a metal filler, for example aluminium, gold, or copper, or any other suitably conductive material. The conductive material is in electric contract with the side surface of the mesa-structure(s) that define the respective trench. In the shown example, the conductive material is physically in contact with the side surface to allow conduction between the conductive material and parts of the mesa-structure with which the conductive material is in contact. However, alternatively, between the conductive material and the side surface of the mesa-structures 112,114 another material may be present, for example another conductive material or a layer of a material which otherwise allows conduction of charge carriers, e.g. an atomic layer which allows tunnelling of charge carriers.

In the shown example, the filling of the trench region 116 extends above the trench 116, and beyond the side surfaces of the mesa-structures, so that the metal overlies the drain contacts 118 of the multi-layer mesa structure 112 and of the another multi-layer mesa structure 114. A suitable height has been found to be for example about 3 μm or more and/or about 10 μm or less from the top of the multi-layer mesa structure 112, although other heights may be used as well. Above the trench region 116, the metal filler may extend in a lateral direction, e.g. parallel to the substrate surface, over the mesa structures 112,114, for example to a suitable width of between for example about 10 μm and about 50 μm (although other widths may be used as well). In the example, the conductive material of the different trenches does not extend laterally beyond the drain contacts 118 or the source contacts 120 respectively, thereby leaving the gate contacts 122, and the mesa-structure between the drains/source contacts and the gate contracts 122 exposed.

As can be seen, opposing neighbouring like contacts, for example drain contacts 118 or source contacts 120, are electrically coupled by the metal filler in and above the trench region 116.

Although described herein in the context of a pair of structures, it should be appreciated that multi-layer mesa structure 112, respective contacts 118, 120, 122 and surrounding metallisation may constitute an independent first power transistor device and the another multi-layer mesa structure 114, respective contacts 118, 120, 122 and surrounding metallisation may constitute another independent second power transistor device. The first and second power transistor devices are however described herein as a pair for the sake of conciseness of description and to facilitate understanding of the structure and operation of the devices. The skilled person should appreciate that the first and second power transistor devices are independent entities and can be controlled as such. Furthermore, the skilled person should appreciate that although the above example has described the wafer 100 as comprising the pair of power transistor devices, the wafer can comprise a greater number of such power transistor devices.

The structure of the shown examples of power transistor devices are such that the power transistor devices are “normally on” type devices and so operation of the power transistor devices will now be described accordingly. However, the skilled person should appreciate that the power transistor devices can be formed so as to be of a “normally off” type.

In operation, a negative bias voltage, V_{GS}, of −5V can be applied between the gate and the source terminals 122, 120, for example of one of the devices, which results in the power transistor device being placed in an OFF state. When in an ON state, a quantum well of about 25 Å in thickness caused by spontaneous and piezoelectric polarisation at the heterojunction results in a 2 Dimensional Electron Gas (2DEG) region forming below the gate terminal 122 and the interface between the GaN channel layer 108 and the barrier layer 110. The 2DEG region constitutes a lateral drift region. However, when the −5V bias voltage, V_{GS}, is applied, the 2DEG region is depleted and so no electrical current flows, resulting in the OFF state.

When the bias voltage, V_{GS}, is increased towards 0V, the depletion of the 2DEG region reduces and the 2DEG region fills with electrons. Due to the presence of the very resistive semi-insulating layer 106, electrical current begins to flow laterally towards the sides of the substrate 100, towards the drain contact 118. As the bias voltage, V_{GS}, is made increasingly positive, the 2DEG region becomes increasingly undepleted and an accumulation of electrons forms in the 2DEG region and contributes to an increased drain current. In this regard, a bias voltage of up to about 300V can be applied between the gate contact 122 and drain contact 118 of the first and/or the second power transistor devices (depending upon which device is being operated), and the source contacts 120 are grounded. The voltage applied at the drain contacts 118 is then raised to a positive voltage of about 600V resulting in improved distribution of an electric field into the bulk material, for example the silicon substrate 100 and the gallium nitride layer 108, because through the conductive material in the trenches the bias voltage is applied not only at the drain and source contacts 118, 120, but also to the sides of the multi-layer mesa structure 112 and the another multi-layer mesa structure 114. Consequently, an improved breakdown voltage is supported by each of the first and second power transistor devices.

It is thus possible to provide a lateral power transistor device and a method of manufacture thereof that results in improved distribution of the electric field of the device in three dimensions, thereby supporting an improved breakdown voltage, which results in reduced die area occupation per device (due to a reduced gate-to-drain distance being required) as well as a reduced normalised on-resistance of the lateral power transistor device. Additionally, the transverse cross-sectional area, relative to the layers of the power transistor device and in a plane between the devices (as shown in the FIG. 8), of the metal deposited on the part-formed device to fill the trench region 116 results in the device having improved heat dissipation properties as well as increased current capability, i.e. the lateral power transistor device can support use in relation to higher electrical currents. Furthermore, due to the smoother ε-field distribution mentioned above, the reliability of the lateral power transistor device is improved, because the electrical stress is less concentrated at the edge of the gate contact facing the drain contact as well as being less concentrated at the device surface.

Of course, the above advantages are exemplary, and these or other advantages may be achieved by the invention. Further, the skilled person will appreciate that not all advantages stated above are necessarily achieved by embodiments described herein.

In the foregoing specification, the invention has been described with reference to specific examples of embodiments of the invention. It will, however, be evident that various modifications and changes may be made therein without departing from the broader spirit and scope of the invention as set forth in the appended claims. For instance, it will be appreciated that the conductive material in the trenches need not be connected to a respective one of the drain and source of the mesa-structure, in which case the electrical field applied to the sides of the multi-layer mesa structure 112 and the another multi-layer mesa structure 114 may be controlled separate from the voltage applied to the contacts 118,120.

Also, although the shown examples of the multi-layer mesa structures have a trapezoid cross-section, the multi-layer mesa structures may have another shape. Furthermore, the multi-layer mesa structures may in other views than the cross-sectional views shown in the figures have another shape and for example in a top-view have a rectangular shape, e.g. be implemented as, parallel, bars extending over the substrate or have other suitable shapes.

Also for example, in one embodiment, the illustrated examples may be implemented as circuitry located on a single integrated circuit or within a same device. For example, as illustrated above, the multi-layer mesa structures 112 and the another multi-layer mesa structures 114 share the common silicon substrate 102. Alternatively, the examples may be implemented as any number of separate integrated circuits or separate devices interconnected with each other in a suitable manner.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps then those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements The mere fact that certain measures are recited in mutually different claims does not indicate that a combination of these measures cannot be used to advantage. Furthermore, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

1. A lateral power transistor device comprising:
a substrate;
a multi-layer mesa-structure situated on the substrate, the multi-layer mesa-structure comprising a heterojunction structure; and
a filled trench filled with a conductive material and situated adjacent to the multi-layer mesa structure, a side surface of said multi-layer mesa-structure being in electric contact with said conductive material.

2. A device as claimed in claim 1, wherein filled trench region substantially abuts the multi-layer mesa structure and the conductive material is in direct contact with the side surface.

3. A device as claimed in claim 1, wherein the conductive material extends, in a direction away from said substrate, beyond the mesa structure.

4. A device as claimed in claim 3, comprising a contact to said heterojunction, and wherein the conductive material extends over, and is in electric contact with, said contact.

5. A device as claimed in claim 4, wherein the contact is situated, in a direction away from said substrate, above said heterojunction structure.

6. A device as claimed in claim 4, wherein the contact constitutes a drain contact or a source contact.

7. A device as claimed in claim 1, wherein the multi-layer mesa structure comprises a semi-insulating layer between the substrate and the heterojunction structure, for electrically isolating the heterojunction structure from said substrate.

8. A device as claimed in claim 7, wherein the semi-insulating layer is formed a material selected from a group consisting of: gallium nitride comprising a p-type dopant, not intentionally doped AlGaN, not intentionally doped InGaN and not intentionally doped AlInN.

9. A device as claimed in claim 1, wherein the heterojunction structure comprises a channel layer, for example made of a III-V nitride such as a gallium nitride.

10. A device as claimed in claim 9, wherein the channel layer is disposed adjacent the semi-insulating layer.

11. A device as claimed in claim 9, wherein the multi-layer mesa structure further comprises a barrier layer disposed and an interface which the channel layer and the barrier layer are in contact with each other.

12. A device as claimed in claim 8, wherein the barrier layer is formed from a material selected from the group consisting of: AlGaN, InGaN and AlInN.

13. A device as claimed in claim 1, wherein the multi-layer mesa structure further comprises a cap layer situated above the heterojunction structure, for protecting at least a part of the heterojunction structure.

14. A device as claimed in claim 1, further comprising a buffer layer between the multi-layer mesa structure and the substrate, said buffer layer electrically isolating the multi-layer mesa structure and the substrate and/or matching crystal structures of the multi-layer mesa structure and the substrate.

15. A device as claimed in claim 14, wherein the buffer layer is a highly resistive or isolating layer, such as a not-intentionally doped aluminium gallium nitride layer.

16. A device as claimed in claim 1, wherein said conducting material is a metal.

17. A semiconductor die comprising:
a first power transistor device comprising the structure of the lateral power transistor device as claimed in claim 1;
a second power transistor device comprising the structure of the lateral power transistor device as claimed in any one of the preceding claims; wherein
the substrate of the first and second power transistor devices is common to both of the first and second power transistor devices, the filled trench region being disposed and shared between a first multi-layer mesa structure of the first power transistor device and a second multi-layer mesa structure of the second power transistor device.

18. A method of manufacturing a vertical power transistor device, comprising:
providing a substrate and a multi-layer structure comprising a heterojunction;
etching a mesa in the multi-layer structure so as to define a side of a neighbouring trench region;
filling the trench region with a conductive material such that the conductive material is situated adjacent to the multi-layer mesa structure and a side surface of said multi-layer mesa-structure is in electric contact with said conductive material.

19. A method as claimed in claim 18, further comprising:
etching another mesa in the multi-layer structure when etching the mesa in the multi-layer structure; wherein
the another mesa defines an opposite side of the neighbouring trench region relative to the side defined by the mesa, the mesa and the another mesa being separated by the trench region.
